(19) United States
(12) Patent Application Publication
(10) Pub. No.: US 2014/0338162 A1
(43) Pub. Date: Nov. 20, 2014

(54) PROCESS FOR PRODUCING DCB SUBSTRATES

(71) Applicant: Curamik Electronics GmbH, Eschenbach (DE)

(72) Inventors: Jurgen Schulz-Harder, Lauf (DE); Karsten Schmidt, Eschenbach (DE); Karl Exel, Rimbach (DE)

(21) Appl. No.: 14/368,968

(22) PCT Filed: Dec. 27, 2012
(86) PCT No.: PCT/DE2012/100400

§ 371 Date: Jun. 26, 2014

(30) Foreign Application Priority Data
Dec. 27, 2011 (DE) 10 2011 057 058.6
Jan. 31, 2012 (DE) 10 2012 100 792.6
Feb. 9, 2012 (DE) 10 2012 101 057.9

(51) Int. Cl. H05K 3/10; H05K 3/14

(52) U.S. Cl. CPC H05K 3/103; H05K 3/14
USPC 29/17.3

(57) ABSTRACT

Process for producing DCB substrates having in each case at least one ceramic layer which is essentially made up of aluminium nitride (AlN) and is provided on at least one surface side with an intermediate layer which is essentially made up of aluminium oxide and also has at least one metallization formed by a metal layer or metal foil on the intermediate layer

### BACKGROUND OF THE INVENTION

The invention relates to a process for producing DCB substrates, particularly in the form of printed circuit boards for electrical circuits and/or modules.

The “DCB process” (DCB stands for Direct Copper Bond technology) is known for joining metal layers or sheets (such as copper sheets or foils) to each other and/or to ceramic or ceramic layers. The process particularly refers to sheets or foils of copper or copper alloys, the surfaces of which have a layer or coating of a chemical compound of the metal and a reactive gas, preferably oxygen.

In this process, which is described, for example, in US-PS 37 44 120 or DE-PS 23 19 854, the layer or coating is combined with the adjacent metal to form a eutectic system (fusion layer) with a melting temperature lower than the melting temperature of the metal (e.g., copper). When the foil is placed on top of the ceramic and all layers are heated, the layers may be bonded with each other, particularly by fusing the metal or copper essentially only in the region of the fusion layer or oxide layer.

This DCB process includes the following process steps:

oxidising a metal foil, e.g., copper foil, in such manner that a uniform metal or copper oxide layer is formed;

placing the metal foil, e.g., copper foil on top of the ceramic layer;

heating the composite up to a process temperature between about 1025 to 1083° C., for example to about 1071° C.; and

cooling to room temperature.

Substrates that have been produced according to this process (also referred to in the following as “DCB bonds”) are referred to in the following as “DCB substrates”, regardless of the metal used for the metal layers or foils.

When ceramic layers of aluminium nitride (AlN) are used, it is also known to first produce an intermediate layer of aluminium oxide (Al₂O₃) on at least one surface side of the respective ceramic layer, by thermal oxidation in Air or in an oxygen-containing atmosphere. This is the only way to enable the metal foil that constitutes the corresponding metallisation, for example the copper foil, to be bonded with ceramic via this intermediate layer using DCB bonds.

It is an object of the invention is to present a process by which DCB substrates having at least one ceramic layer consisting essentially of aluminium nitride may be produced with improved quality, particularly with improved mechanical and/or electrical and/or thermal properties.

### SUMMARY OF THE INVENTION

An essential feature of the process according to the invention is that each ceramic layer used consists essentially of aluminium nitride (AN), for example with an aluminium nitride component of at least 90%, preferably with an aluminium nitride component of at least 96%, wherein further components include sintering aids such as yttrium oxide (Y₂O₃), calcium oxide (CaO), magnesium oxide (MgO) and releasing agents such as boron nitride (BN) and reaction products such as garnet (Y₂O₃—Al₂O₃) and boron oxide (B₄O₃), and is cleaned by mechanical and/or chemical means, that is to say a surface layer resulting from the sintering process is removed therefrom before production of the at least one intermediate layer of aluminium oxide (Al₂O₃), and includes reaction processes from the sintering process.

In a refinement of the invention, the process is structured such that the surface layer, particularly the surface layer containing an oxide ceramic, is removed mechanically, for example by brushing, grinding, lapping, sand blasting, pressure blasting and/or the surface layer is removed by chemical treatment, for example by treatment with an alkaline solution, preferably an aqueous solution with a pH value higher than 10, preferably with a pH value higher than 12.

The surface layer is removed at a treatment temperature in the range between 20° C. and 100° C., preferably at a temperature above 50° C.

The surface layer is removed by treatment with caustic soda, preferably a 5% caustic soda solution and/or by treatment with potassium hydroxide (KOH) and/or sodium carbonate (Na₂CO₃), and/or the surface layer is removed by the application of heat in a liquid and/or steam, for example by treatment under pressure in an autoclave at temperatures up to 300° C.

A thin layer of copper or copper oxide, or of at least one other copper-containing compound is applied to at least one surface side of the ceramic layer before the at least one intermediate layer is created, and the at least one intermediate layer is produced subsequently by thermal oxidation.

Thermal oxidation continues until a layer thickness in the range between 0.5 μm and 10 μm has been reached for the at least one intermediate layer (3).

The mechanical and chemical treatments for removing the at least one surface layer are carried out at least partly concurrently or consecutively.

The thin layer of copper or copper oxide or the at least one copper-containing compound is applied by immersing the ceramic layer in an aqueous solution containing copper ions, for example an aqueous solution containing 0.005 to 2.0 Mol/l Cu++ ions.

The thin layer of copper or copper oxide or the at least one other copper-containing compound is applied by sputtering and/or by chemical vapour deposition and/or by chemical precipitation.

The at least one intermediate layer is created by thermal oxidation, that is to say by heating the ceramic layer to a temperature in the range between 800° C. and 1450° C. in air or in an oxygen-containing atmosphere with an oxygen component between 10% and 90%.

The process of producing the DCB substrate comprises the steps of:

1) placing at least one oxidised metal foil made from copper or a copper alloy on top of at least one surface side of the cleaned AlN ceramic layer,

2) heating the at least one metal foil and the ceramic layer to a temperature between 400° C. and 1083° C.,

3) removing the at least one metal foil, preferably after cooling the metal foil and the ceramic layer,

4) oxidising the ceramic layer at a temperature of 850° C.-1450° C. in an oxygen-containing atmosphere to produce the intermediate layer on at least one surface side of the ceramic layer, and

5) DCB bonding at least one metal foil with at least one surface side of the ceramic layer.

Alternatively, the process comprises the following steps of:

1) oxidising the cleaned AlN ceramic layer at a temperature from 800° C.-1450° C.,

2) DCB bonding at least one metal foil made from copper or a copper alloy on at least one surface side of the oxidised ceramic layer,

3) removing the at least one metal foil, preferably by etching,

4) oxidising the ceramic layer (2) again, at a temperature from 800° C.-1450° C., and

5) DCB bonding at least one metal foil on at least one surface side of the ceramic layer.

Alternatively, the process comprises the following steps of

1) producing a green foil from aluminium nitride and sintering agents by casting and/or calendering and/or compacting, and a blank ceramic layer is produced from said foil by sintering, the intermediate layer is produced on at least one surface side of the ceramic layer, and the previously oxidised metal layer or metal foil is then bonded therewith by DCB bonding technology, and

2) removing a surface layer resulting from the sintering process and present on the surface side of the ceramic layer in question before the at least one intermediate layer is produced thereon, and the intermediate layer is produced subsequently, wherein each of features cited previously may be used either individually or in any combination with each other.

For the purposes of the invention, the expressions “substantially” or “about” are used to indicate deviations by +/−10%, preferably by +/−5%, from the respective exact values and/or tolerances in the form of variations that are without significance for function.

Refinements, advantages and application possibilities of the invention will be evident from the following description of exemplary embodiments and from the figures. In this context, all features that are described and/or illustrated in the drawings constitute the object of the invention without exception, either alone or in any combination thereof, regardless of the terms in which they are defined.

### BRIEF DESCRIPTION OF THE DRAWINGS

The invention will be described in greater detail with reference to the figures illustrating exemplary embodiments thereof. In the drawing:

FIG. 1 is a cross-section through a DCB substrate with an insulating or ceramic layer of aluminium nitride (AlN);

FIG. 2 various process steps in diagrams a)-f) for producing the DCB substrate of FIG. 1;

FIG. 3 an enlarged representation of the aluminium nitride ceramic layer together with an intermediate ceramic layer deposited thereon, consisting substantially of aluminium oxide (Al₂O₃) in the process of FIG. 2;

FIG. 4 in diagrams a)-f), various process steps for producing the DCB substrate of FIG. 1 in another embodiment of the invention; and

FIG. 5 an enlarged representation of the aluminium nitride ceramic layer together with an intermediate ceramic layer deposited thereon, consisting substantially of aluminium oxide (Al₂O₃) in the process of FIG. 4.

### DETAILED DESCRIPTION OF THE INVENTION

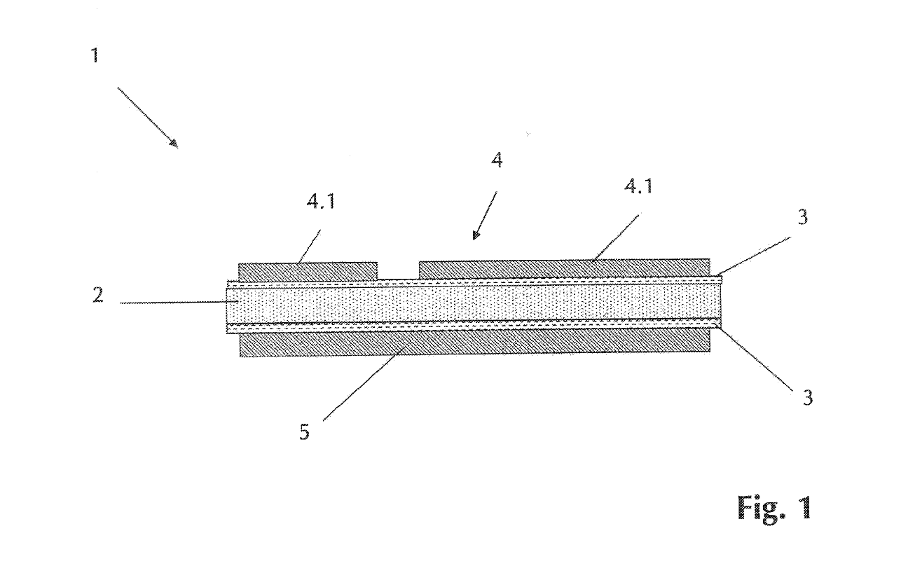

FIG. 1 shows 1 a metal-ceramic substrate, a DCB substrate, composed of a ceramic layer 2 of protective or intermediate layers 3, each of which is located on a surface side of ceramic layer 2, and of metallisations 4 and 5, each of which is deposited on one of intermediate layers 3, and from which the metallisation 3 is structured to create areas of metal 3.1 in the form of e.g., conductor paths, contact surfaces, mounting surfaces and the like.

In detail, ceramic layer 2 is a layer of aluminium nitride (AlN), including a content of at least 90% by weight, preferably a content of about 96% by weight of aluminium nitride (AlN), wherein the rest is made up of further additives or substantially of further additives, particularly sintering agents, such as yttrium oxide (Y₂O₃), calcium oxide (CaO), barium oxide (B₂O₃), barium nitride (BN), calcium oxide (CaO) and similar.

Intermediate layers 3 are also ceramic layers, and they consist essentially of aluminium oxide (Al₂O₃) with a small percentage of other ingredients, particularly sintering aids, for example a small proportion of yttrium oxide (Y₂O₃), barium nitride (BN), barium oxide (B₂O₃), calcium oxide (CaO). Metallisations 4 and 5 are layers made from foils of copper, a copper alloy, aluminium or an aluminium alloy.

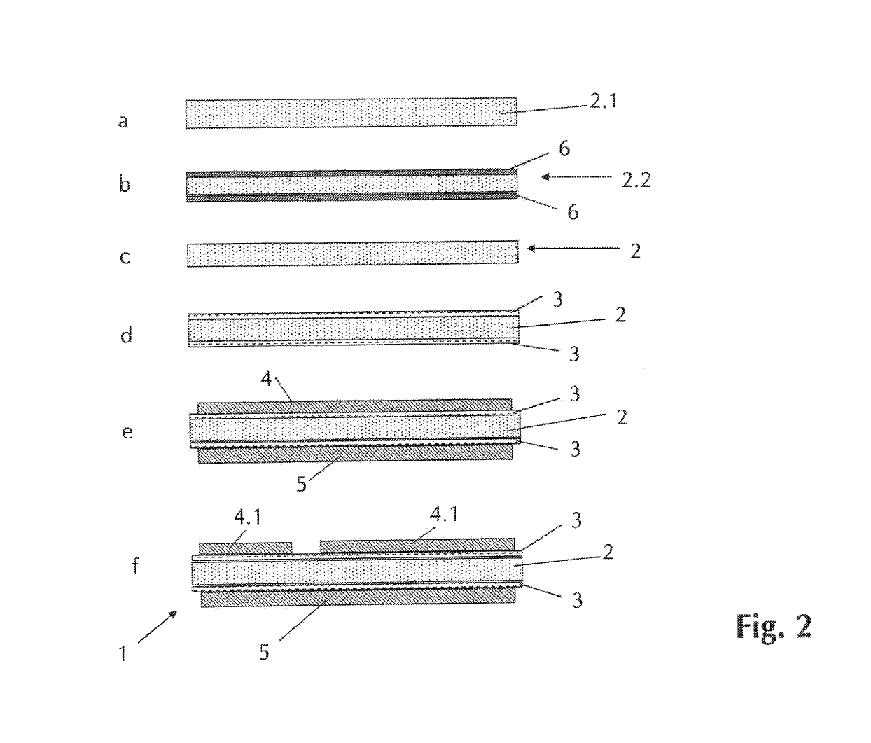

The basic process steps for producing the substrate 1 are reflected by diagrams a)-f) in FIG. 2.

According to diagram a), the ceramic layer 2 is first prepared from aluminium nitride by casting and/or calendaring and/or compacting a green foil 2.1 of aluminium nitride (AlN) together with the sintering aids, and subsequently sintering the resulting green foil 2.1, also in a stack with other green foils at the requisite sintering temperature, for example at a temperature in the range between 1600° C. and 1900° C. After the sintering step, the blank ceramic layer 2.2 (ceramic layer as-fired) shown in diagram b) is obtained.

When sintering is carried out in a stack, releasing agents such as boron nitride (BN) are used. This blank ceramic layer 2.2 particularly includes surface layers 6 that are formed as a result of the sintering process, having a thickness for example in the range from 0.05 mm to 0.3 mm. The surface layers 6 consist essentially of impurities and components or compounds of the sintering aids and the releasing agents, for example boron oxide (B₂O₃), boron nitride (BN), yttrium oxide (Y₂O₃), garnet ((Y₂O₃′Al₂O₃), calcium oxide (CaO), and so on.

As shown in diagram c), in a next process step surface layer 6 is removed, so that ceramic layer 2 is obtained with cleaned or cleared surface sides.

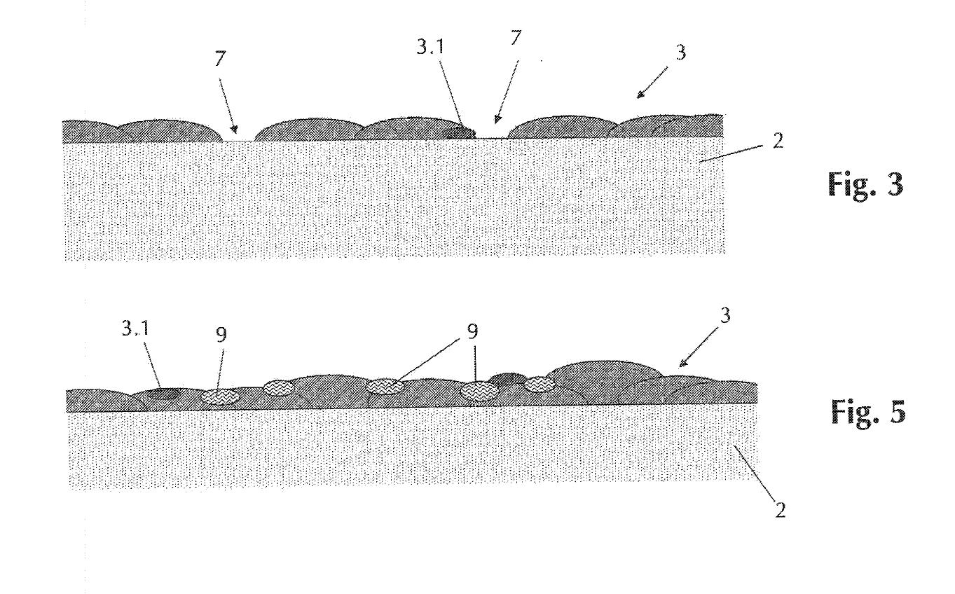

In a next process step, as shown in diagram d), intermediate layers 3 are applied, for example by thermal oxidation. For this purpose, ceramic layer 2 is heated to a temperature in the range between 800° C. and 1450° C. in air or an oxygen-containing atmosphere, for example an atmosphere that contains an inert gas, for example nitrogen, argon and the like, and oxygen in a proportion of 10%-90%. Intermediate layers 3 also contain components (3.1) or reaction products of the sintering aids, for example Y₂O₃, BN, B₂O₃ etc. (FIGS. 3 and 5).

In a further process step, as shown in diagram e), the DCB bonding or area bonding of the metal layers or metal foils consisting essentially of copper or a copper alloy, aluminium or an aluminium alloy that form metallisations 4 and 5. For this purpose, the previously oxidised metal layers or metal foils are each placed on top of an intermediate layer 3 and then bonded with intermediate layers 3 and via ceramic layer 2. DCB bonding is carried out by heating the arrangement produced by the metal foils or layers and ceramic layer 2 with intermediate layers 3 up to the DCB temperature in the range between 1025° C. and 1083° C. in a protective gas or inert gas atmosphere with a low percentage of oxygen, and subsequent cooling to ambient temperature. In this way, the respective copper or aluminium oxide and the adjacent copper or aluminium combine to form a eutectic melt via which, after cooling to below the DCB temperature, the metal layer of metal foil that forms the respective metallisation 4 or 5 is bounded with the adjacent intermediate layer 3, and through this intermediate layer also bonded with ceramic layer 2. With the intermediate layers 3, the ceramic is moistened as required with the liquid eutectic system, and this is the only way in which DCB bonding of metallisations 4 and 5 and of the metal layers or metal foils that form these metallisations is possible.

In a further process step, as shown in diagram f), at least metallisation 4 is structured to form metal areas 4.1, which are also electrically separated from each other, using a suitable, known masking and etching method. This structuring may be omitted if metallisations 4 and 5, and particularly metallisation 4, are structured before their application to the ceramic layer 2 with the intermediate layers 3 disposed on top by DCB bonding.

Various methods are possible for removing surface layers 6, particularly a mechanical and/or a material removing treatment and/or a chemical treatment, such as a chemical treatment with a suitable aqueous or caustic solution, preferably with an aqueous, alkaline solution having a pH value higher than 10, or preferably higher than 12, preferably by immersing the blank ceramic layer 2.2 in said aqueous or caustic solution.

In this context, caustic soda (NaOH), and especially a 5% solution thereof, has proven to be a particularly suitable treatment solution. However, other alkaline treatment solutions are also suitable, for example KOH, Na₂CO₃. The treatment preferably takes place at a temperature in a range between 20° C. and 100° C., preferably at a temperature above 50° C. Another option is to carry out the treatment with the named solutions under pressure in an autoclave up to 300° C. This enables treatment times to be shortened significantly.

A mechanical treatment designed to remove the material of surface layers 6, for example removal of the surface layers 6 by brushing and/or grinding and/or lapping, sand blasting, pressure blasting etc., is also possible in addition to or instead of the chemical treatment.

In one embodiment of the process according to the invention, the mechanical treatment is carried out before the chemical treatment or immediately after the chemical treatment. In a preferred embodiment of the process according to the invention, the mechanical treatment and the chemical treatment are carried out at least partly concurrently.

It has also been found that when the process according to the invention is used, particularly good results are obtained, especially in terms of the mechanical strength and quality of the bond between metallisations 4 and 5 and the ceramic, and with regard to the electrical properties thereof, if copper or copper oxide and/or copper ions are embedded in the intermediate layer 3. In fact, it was found that if copper or copper oxide and/or copper ions is/are not embedded in intermediate layers 3, discontinuities 7 arise, at which points the respective intermediate layer 3 is incomplete or interrupted.

As a consequence of these discontinuities 7, particularly the pores and interruptions, no DCB bonding takes place between the ceramic and the respective metallisation 4 or 5 in the area of the discontinuities 7, so bubbles or cavities form below the respective metallisation 4 and 5. These bubbles or cavities not only impair the mechanical strength of the bound between metallisations 4 and 5 and the ceramic, they also have a critically negative effect on the dielectric strength of substrate 1 between metallisations 4 and 5. If copper or copper oxide and/or copper ions are embedded in intermediate layers 3, discontinuities 7 and the disadvantages associated therewith are effectively avoided (FIG. 5).

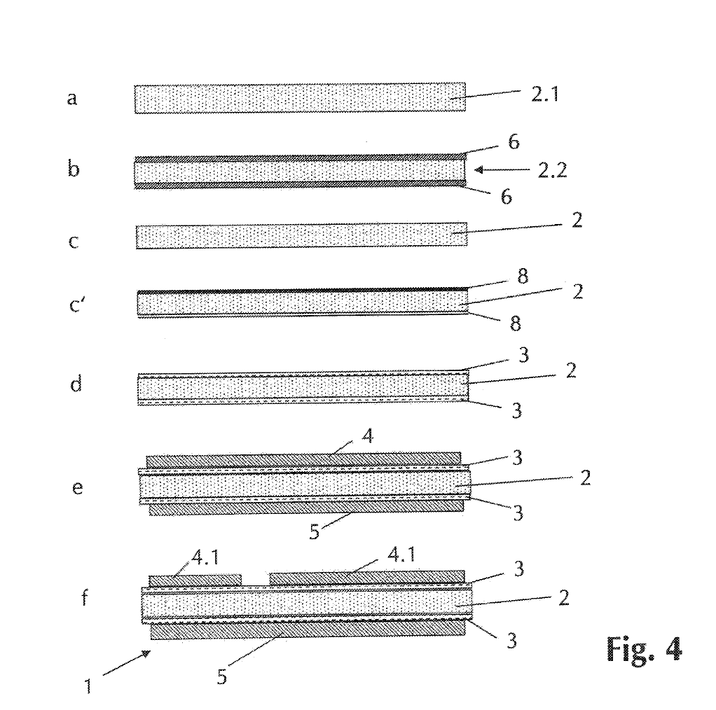

The copper, copper oxide or copper ions may be embedded in various ways. Diagrams a-f in FIG. 4 illustrate the principal steps of a method in which, after the green ceramic 2.1 is provided (diagram a), after the green ceramic has been sintered and cleaned 2.2 (diagrams b and c), a thin layer 8 of copper or a copper containing compound is applied to both surface sides of the ceramic layer 2 that has been cleaned, i.e., from which surface layers 6 have been removed, as is indicated in the diagram c)′ following diagram c) in FIG. 4. Following this process, the two intermediate layers 3 are created to the required thickness by thermal oxidation in an oxygen containing atmosphere, as shown in diagram d). In these processes also, intermediate layers 3 are adjusted to a layer thickness between about 0.5 μm and 10 μm.

The subsequent process steps (diagrams e) and f)) reflect the process as it was described with reference to FIG. 2. Layers 8 are applied for example with a thickness in the range between 1.5×10⁻⁴ μm and 1200×10⁻⁴ μm. Layers 8 may be applied for example by immersing the cleaned ceramic layer 2 in an aqueous solution containing copper ions, for example an aqueous solution with 0.005 to 2.0 Mol/l Cu++ ions and/or by sputtering and/or by chemical vapour deposition and/or by chemical precipitation. During mechanical removal of surface layers 6, layers 8 may also be produced by using brushes with copper containing bristles.

Another way to dope the Al₂O₃ intermediate layers 3 with copper during thermal oxidation may include the following process steps:

cleaning the ceramic or ceramic layer 2 using the methods described previously,

placing oxidised copper foils on ceramic layer 2,

heating ceramic layer 2 and the copper foils in a DCB process atmosphere to a temperature from 400° C.-1083° C.,

cooling ceramic layer 2 and the copper foils to room temperature, and

oxidising ceramic layer 2 according to the method described in the preceding at temperatures from 850° C.-1450° C. to produce intermediate layer 3, wherein the copper foils used are preferably removed before this oxidation.

Another way to dope the Al₂O₃ intermediate layers 3 with copper may include the following process steps:

cleaning the ceramic or ceramic layer 2 using the methods described previously,

oxidising ceramic layer 2 without copper doping at a temperature from 800° C.-1450° C. to produce an Al₂O₃ intermediate layer 3 that still contains discontinuities 7,

DCB bonding oxidised copper foils onto intermediate layers 3,

removing the copper foils, for example by chemical etching, and

repeating the oxidation of ceramic layer 2 at temperatures from 800° C.-1450° C. to produce intermediate layers 3.

In both of the methods described above, copper/copper oxide is also embedded in Al₂O₃ intermediate layers 3.

The embedding 9 of copper/copper oxide produces intermediate layers 3 that are free from flaws and discontinuities, as is indicated in FIG. 5.

The invention has been described the preceding on the basis of exemplary embodiments thereof. Of course, many modifications and variations are possible without thereby departing from the inventive idea on which the invention is based.

### LIST OF REFERENCE SIGNS

1 Substrate
2 Ceramic layer
2.1 Green foil made from ceramic mass
2.2 Burned blank ceramic
3 Intermediate layer
4, 5 Metallisation
4.1 Metal area
6 Surface layer
7 Flaw or interruption
8 Layer of copper, copper oxide or copper ions
9 Copper containing deposits

1. A process for producing DCB substrates having at least one ceramic layer (2) consisting essentially of aluminium nitride (ALN), wherein at least one surface side of the at least one ceramic layer is has an intermediate layer consisting essentially of aluminium oxide Al₂O₃), and at least one metallisation formed by a metal layer on the intermediate layer, wherein a green foil is produced from the aluminium nitride and sintering agents by casting, calendering and/or compacting, and a blank ceramic layer is thereby produced from the green foil by sintering, and wherein the intermediate layer is thereby produced on the at least one surface side of the at least one ceramic layer, and the metal layer is then bonded with the intermediate layer by DCB bonding, wherein before production of the intermediate layer on the surface side of the at least one ceramic layer, a surface layer resulting from the sintering containing impurities and/or reaction products is removed therefrom.

2. The process according to claim 1, whereby removal of the surface layer is carried out by brushing, grinding, lapping, sand blasting, or pressure blasting.

3. The process according to claim 1, wherein removal of the surface layer is carried out by chemical treatment with an alkaline aqueous solution having a pH value greater than 10.

4. The process according to claim 3, wherein the surface layer is removed at a treatment temperature range between 20° C. and 100° C.

5. The process according to claim 3, wherein the surface layer (6) is removed by the chemical treatment with, a 5% caustic soda solution and/or by the chemical treatment with a potassium hydroxide (KOH) and/or sodium carbonate (Na₂CO₃).

6. The process according to claim 1, wherein the surface layer is removed by application of heat in a liquid and/or steam under pressure in an autoclave at temperatures up to 300° C.

7. The process according to claim 1, wherein a thin layer of copper, copper oxide, or of at least one other copper-containing compound is applied to the at least one surface side of the ceramic layer before the intermediate layer is created, and the intermediate layer is produced subsequently by thermal oxidation.

8. The process according to claim 7, wherein the thermal oxidation continues until a layer thickness in the range between 0.5 μm and 10 μm has been reached for the intermediate layer.

9. The process according to claim 1, wherein the mechanical and chemical treatments for removing the surface layer are carried out at least partly concurrently or consecutively.

10. The process according to claim 7, wherein the thin layer of copper, copper oxide or of the at least one copper-containing compound is applied by immersing the at least one ceramic layer in an aqueous solution containing from 0.005 to 2.0 Mol/l copper ions.

11. The process according to claim 7, wherein the thin layer of copper, copper oxide or of the at least one copper-containing compound is applied by sputtering, by chemical vapour deposition and/or by chemical precipitation.

12. The process according to claim 1, wherein the intermediate layer is created by heating the at least one ceramic layer to a temperature in the range between 800° C. and 1450° C. in air or in an oxygen-containing atmosphere with an oxygen component between 10% and 90%.

13. A process for producing DCB substrates comprising the steps of:
1) placing at least one oxidised metal foil made from copper or a copper alloy on top of at least one surface side of a cleaned aluminium nitride (AlN) ceramic layer;
2) heating the at least one oxidised metal foil and the cleaned aluminium nitride (AlN) ceramic layer to a temperature between 400° C. and 1083° C.;
3) removing the at least one oxidised metal foil, after cooling the at least one oxidised metal foil and the cleaned aluminium nitride (AlN) ceramic layer;
4) oxidising the cleaned aluminium nitride (AlN) ceramic layer at a temperature of 850° C.-1450° C. in an oxygen-containing atmosphere to produce an intermediate layer on at least one surface side of the cleaned aluminium nitride (AlN) ceramic layer; and
5) DCB bonding the at least one oxidised metal foil with the at least one surface side of the cleaned aluminium nitride (AlN) ceramic layer.

14. A process for producing DCB substrates, comprising the steps of:
1) oxidising the a cleaned aluminium nitride (AlN) ceramic layer at a temperature from 800° C.-1450° C to form an oxidised ceramic layer;
2) DCB bonding at least one metal foil made from copper or a copper alloy on at least one surface side of the oxidised ceramic layer;
3) removing the at least one metal foil by etching;
4) oxidising the ceramic layer again, at a temperature from 800° C.-1450° C; and
5) DCB bonding the at least one metal foil on at least one surface side of the ceramic layer.
